(19) United States
(12) Patent Application Publication
(10) Pub. No.: US 2016/0379806 A1
(43) Pub. Date: Dec. 29, 2016

(54) USE OF PLASMA-RESISTANT ATOMIC LAYER DEPOSITION COATINGS TO EXTEND THE LIFETIME OF POLYMER COMPONENTS IN ETCH CHAMBERS

(71) Applicant: Lam Research Corporation, Fremont, CA (US)

(72) Inventors: Lin XU, Katy, TX (US); Nash W. ANDERSON, Cupertino, CA (US); John DAUGHERTY, Fremont, CA (US); Thomas R. STEVENSON, Morgan Hill, CA (US); John Michael KERNS, Livermore, CA (US)

(21) Appl. No.: 14/750,714

(22) Filed: Jun. 25, 2015

(51) Int. Cl. H01J 37/32; H02N 13/00; C23C 16/06; H01L 21/683; B32B 37/12; C23C 16/455

(52) U.S. Cl. CPC H01J 37/32495; H01J 37/32715; H01J 37/32513; H01J 37/32642; B32B 37/1284; C23C 16/45525; C23C 16/06; H01L 21/6833; H02N 13/00; B32B 2311/24; B32B 2315/02

(57) ABSTRACT

In accordance with this disclosure, there are provided several inventions, including an apparatus and method for depositing plasma resistant coatings on polymer materials used in a plasma processing chamber. In a particular example, such a coating may be made on a portion of an electrostatic chuck, where the polymer material is a bead surrounding an adhesive between a chuck base and a ceramic top plate.

### BACKGROUND

This disclosure relates to the coating of polymer components in etch chambers used in semiconductor processing.

Polymer components have many uses within plasma processing chambers, including rings, seals, and bushings. To maximize lifetime of polymer components, prior designs have used plasma-resistant polymers. One dilemma is that some polymers could be resistant against one type of radical (e.g., the F radical) but not others (e.g., O or H radicals). Another challenge is that achieving one order difference in erosion rate of polymers by engineering the chain structure may not be a simple task even for a highly skilled polymer chemist, because one must balance against other properties of the materials.

Another strategy is to add plasma resistant metallic oxide fillers into the polymer matrix to retard the attacks of radicals. However, polymer materials could be preferentially etched by radicals, leaving filler materials loose and potentially flaking off as a particle source.

New ways are therefore needed to extend the lifetime of polymer components in plasma chambers.

### SUMMARY

Disclosed herein are various embodiments, including an electrostatic chuck (ESC) for a plasma processing chamber. This ESC may in one embodiment comprise aluminum or aluminum alloy. It may further include a ceramic top plate for holding a wafer, bonded to the base. It may have a polymer material between the base and the ceramic top plate, with at least one exposed portion, and a plasma resistant atomic layer deposition coating on the at least one exposed portion.

In various further embodiments of the above electrostatic chucks, the ceramic top plate may be bonded to the base by an adhesive, and the polymer material may comprise a bead surrounding the adhesive. The plasma resistant atomic layer deposition coating may be a dielectric material. The plasma resistant atomic layer deposition coating may comprise alumina. The plasma resistant atomic layer deposition coating may comprise an oxide comprising yttrium. The polymer material may comprise strengthening additives for enhanced mechanical properties. The base may comprise gas distribution channels. The above ESC may also be part of a plasma processing chamber, and also may include an O-ring. This O-ring may comprise a plasma resistant atomic layer deposition coating.

This application also describes embodiments of a confinement ring for a plasma processing chamber. This confinement ring may include a support structure for supporting the confinement ring. This support structure may comprise a polymer material. This polymer material may be coated by a plasma resistant atomic layer deposition coating.

In various further embodiments of the above confinement rings, the polymer material may comprise polyimide. The plasma resistant atomic layer deposition coating may also be alumina.

This application also describes methods of making an electrostatic chuck for a plasma processing chamber. This method may include any or all of the following steps: providing a base comprising aluminum or aluminum alloy; providing a ceramic top plate for holding a wafer; bonding the ceramic top plate to the base; applying a polymer material between the base and the ceramic top plate, having at least one exposed portion; and depositing by atomic layer deposition a plasma resistant layer on the at least one exposed portion.

In various further embodiments of the above methods, the step of bonding may comprise joining the ceramic top plate to the base with an adhesive. The step of applying a polymer material may also comprise applying a polymer bead surrounding the adhesive. The plasma resistant atomic layer deposition coating may be a dielectric material. The plasma resistant atomic layer deposition coating may comprise alumina. The plasma resistant atomic layer deposition coating may comprise an oxide comprising yttrium. The polymer material may comprise strengthening additives for enhanced mechanical properties. The base may comprise gas distribution channels.

These and other features of the present inventions will be described in more detail below in the detailed description and in conjunction with the following figures.

### BRIEF DESCRIPTION OF THE DRAWINGS

The disclosed inventions are illustrated by way of example, and not by way of limitation, in the figures of the accompanying drawings and in which like reference numerals refer to similar elements and in which:

FIG. 1 is a schematic cross-sectional view of an example electrostatic chuck and wafer.

FIG. 2 is a schematic cross-sectional view of a coated confinement ring, including a hanger, for use in a plasma chamber.

FIG. 3 is a schematic cross-sectional view of a coated o-ring for use in a plasma chamber.

### DETAILED DESCRIPTION

Inventions will now be described in detail with reference to a few of the embodiments thereof as illustrated in the accompanying drawings. In the following description, specific details are set forth in order to provide a thorough understanding of the present invention. However, the present invention may be practiced without some or all of these specific details, and the disclosure encompasses modifications which may be made in accordance with the knowledge generally available within this field of technology. Well-known process steps and/or structures have not been described in detail in order to not unnecessarily obscure the present disclosure.

Polymers have many uses within plasma processing chambers; for example, as the polymer bead or seal for an electrostatic chuck, as polyamide-imide bushings, or as polyimide laminate rings. Due to their organic nature, polymers are susceptible to radical attacks even in the absence of ion bombardment within plasma etchers, for example by attacking C—C or Si—O bonds. This either shortens the lifetime of consumable parts made from polymers, or even worse, jeopardizes the lifetime of a whole assembly.

In one embodiment, the lifetime of polymer components may be extended by using an atomic layer deposition (ALD) coating as a radical-resistant protective barrier to completely shield polymers from radical attacks. Example ALD coating materials may include ceramics, dielectric materials, alumina, zirconia, yttria, combinations of aluminum, zirconium, yttrium, and/or oxygen such as YAG or YSZ, and materials known in the art to have superior resistance to radicals. The material may in several embodiments also be metal oxide, nitride, fluoride, or carbide, or combinations thereof.

ALD coatings as used in the context of these embodiments may be super-conformal and uniform, and have numerous other advantages such as increasing the lifetime of a polymer part and reducing sources of contamination. The ALD coatings can be operated at low temperature (even at room temperature) which will not compromise structural and chemical properties of polymers (e.g., soften the polymer). The coatings can be pinhole or pore free, and provide a superior radical barrier.

Another advantage for use in coating polymer materials in plasma processing chambers is that ALD coatings are typically very pure, and can be made to show no detectable metal impurities, perhaps other than Aluminum from coating. Carbon impurity within film can also be made low.

ALD coatings of polymers can be super-conformal and uniform, and exhibit a coating thickness that is independent of aspect ratio. The coating need not alter the part dimension, which can be important for many components such as thermal interface materials, sacrificial protection shims, or O-rings. In addition, a very thin ALD coating need not interfere with the functionality of coated parts such as thermal interface materials by adding thermal impedance.

Furthermore, ALD coatings can be made flexible, which can make them suitable for flexible polymer parts. An ALD inorganic coating can be used, for example, as a moisture barrier for flexible displays. Without being bound by theory, a mechanism of its flexibility may be its low thickness or amorphous structure.

Methods of ALD coating are known in the art. See, e.g., U.S. Patent Pub. No. 2014/0113457 A1 (published Apr. 24, 2014), incorporated herein by reference in its entirety. They use surface-mediated deposition reactions to deposit films on a layer-by-layer basis. In one example ALD process, a substrate surface, including a population of surface active sites, is exposed to a gas phase distribution of a first film precursor (P1). Some molecules of P1 may form a condensed phase atop the substrate surface, including chemisorbed species and physisorbed molecules of P1. The reactor is then evacuated to remove gas phase and physisorbed P1 so that only chemisorbed species remain. A second film precursor (P2) is then introduced to the reactor so that some molecules of P2 adsorb to the substrate surface. The reactor may again be evacuated, this time to remove unbound P2. Subsequently, thermal energy provided to the substrate activates surface reactions between adsorbed molecules of P1 and P2, forming a film layer. Finally, the reactor is evacuated to remove reaction by-products and possibly unreacted P1 and P2, ending the ALD cycle. Additional ALD cycles may be included to build film thickness.

Polymer components for plasma chambers which may be suitable for coating with ALD layers may include any components that are susceptible to radical erosion in plasma etch, as well as deposition, or which are in downstream chambers. Non-limiting examples may include:
elastomeric O-rings;
epoxy or silicone electrostatic chuck beads and E-bands;
sacrificial Cirlex® (laminated polyimide) shims;
thermal interface materials such as Qpad® (composite of aluminum foil and conductive rubber);
PEEK (polyetheretherketone) hangers for confinement rings; and
Torlon® (polyamide-imide) bushing and Cirlex® rings.

In one embodiment, polymer parts may be coated via ALD prior to assembly in the chamber. In another embodiment, parts may be coated after the chamber is assembled, or part of a chamber is assembled. For example, an electrostatic chuck may be assembled including polymer parts, and the entire electrostatic chuck may be coated via ALD.

ALD coatings over a polymer for use in a plasma chamber according to the embodiments disclosed herein may be very thin, or may have a wide range of thicknesses. For example, the thickness may in one embodiment be in the range of about 10 nm to about 1 μm. Preferably, the range may be from about 100 nm to about 500 nm.

### Examples

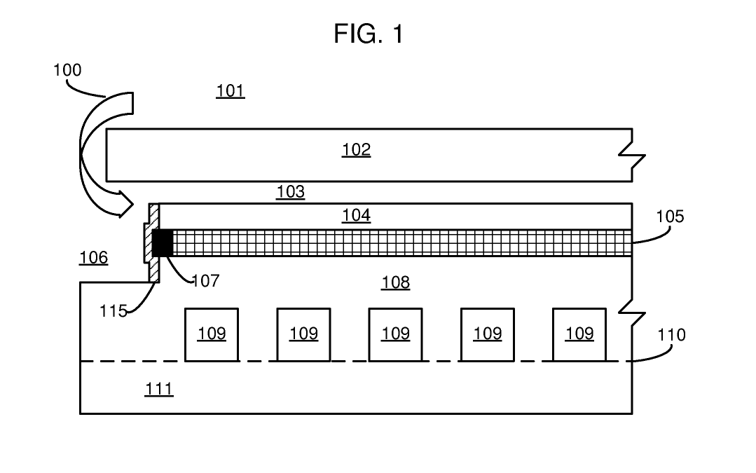

FIG. 1 is a schematic cross-sectional view illustrating one example of an application for ALD coating of plasma chamber polymer components. The chamber in this example comprises an electrostatic chuck. The base of the chuck may include fluid channels 109, typically for cooling, and may be formed of two pieces, including a top piece 108 and a bottom piece 111. In one embodiment, pieces 108 and 111 may be aluminum, and may be joined together by brazing or other means 110, to form channels 109 for a cooling fluid such as water. In this embodiment, the joined chuck base may be bonded to a ceramic plate 104 by an adhesive polymer 105. During processing, a wafer 102 may be placed on the ceramic plate 104, and there may be a small gap 103 between them. In some embodiments, a polymer bead 107 may be placed around the adhesive polymer 105.

In one embodiment, the ceramic plate 104 comprises a dielectric material. In another embodiment, it comprises alumina.

During operation, the plasma chamber area 101 may produce radicals such as F radical, which may flow (100) around the edge of the wafer into the region 106 around the adhesive 105 or the polymer bead 107. Adhesive 105 (or if present, bead 107) may be coated by ALD on at least the side facing area 106 with a plasma resistant coating, such that the ALD coating 115 will be resistant to radical attack.

In one embodiment, the plasma resistant coating 115 may be a dielectric material. In another embodiment, the coating may comprise alumina. In another embodiment, the adhesive material 105 may comprise strengthening additives, such as fibers or particles, for enhanced mechanical properties. In previous designs, the strengthening additives to polymers were detrimental because of the possibility of contamination. However, coating an strengthened polymer material by ALD makes it possible to seal such additives within the coating, thus allowing the use of strengthened polymer materials inside a plasma processing chamber.

Some plasma processing chambers use confinement rings in order to confine plasma to a particular location within the chamber. In some configurations, such as that described in U.S. Patent Application Pub. No. 2012/0073754 A1 (published Mar. 29, 2012, incorporated herein by reference in its entirety), such confinement rings may be positioned using hangers made of polymer materials such as PEEK (polyetheretherketone).

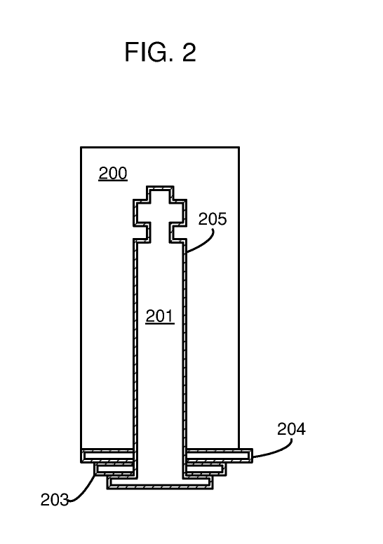

FIG. 2 is a schematic illustration of a confinement ring 200, secured by hanger 201. In this example, the hanger 201 is made of PEEK. Prior to installation, it may be coated with a plasma-resistant coating 205 such as alumina, via atomic layer deposition. In various embodiments, this assembly may also include a lower ring 204 below the confinement ring, which in this example may also be made of PEEK and coated by atomic layer deposition. A washer 203 may also be used under the hanger, which also may be made of PEEK and coated by atomic layer deposition. In an alternative embodiment, the confinement ring 200 may be installed, and the lower ring 204, hanger 201, and in one embodiment the washer 203 may be installed first, and then the entire assembly coated by atomic layer deposition.

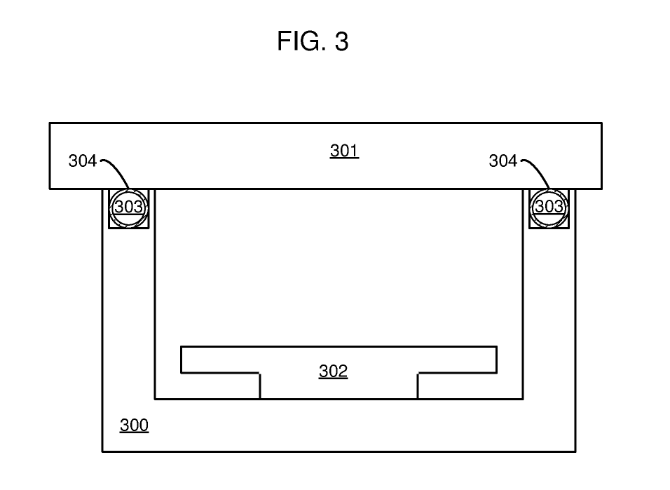

FIG. 3 is a simple schematic illustration of a plasma processing chamber containing an electrostatic chuck 302 with an o-ring 303 connecting the chamber body 300 with a chamber top 301. The o-ring in this example may have a coating 304 with alumina, via atomic layer deposition.

While inventions have been described in terms of several preferred embodiments, there are alterations, permutations, and various substitute equivalents, which fall within the scope of this invention. There are many alternative ways of implementing the methods and apparatuses disclosed herein. It is therefore intended that the following appended claims be interpreted as including all such alterations, permutations, and various substitute equivalents as fall within the true spirit and scope of the present invention.

What is claimed is:

1. An electrostatic chuck for a plasma processing chamber, comprising:
a base comprising aluminum or aluminum alloy;
a ceramic top plate for holding a wafer, bonded to the base;
a polymer material between the base and the ceramic top plate, having at least one exposed portion; and
a plasma resistant atomic layer deposition coating on the at least one exposed portion.

2. The electrostatic chuck of claim 1, wherein the ceramic top plate is bonded to the base by an adhesive, and wherein the polymer material comprises a bead surrounding the adhesive.

3. The electrostatic chuck of claim 1, wherein the plasma resistant atomic layer deposition coating is a dielectric material.

4. The electrostatic chuck of claim 1, wherein the plasma resistant atomic layer deposition coating comprises alumina.

5. The electrostatic chuck of claim 1, wherein the plasma resistant atomic layer deposition coating comprises an oxide comprising yttrium.

6. The electrostatic chuck of claim 1, wherein the polymer material comprises strengthening additives for enhanced mechanical properties.

7. The electrostatic chuck of claim 1, wherein the base comprises gas distribution channels.

8. A plasma processing chamber comprising the electrostatic chuck of claim 1, further comprising an O-ring, wherein the O-ring comprises a plasma resistant atomic layer deposition coating.

9. A confinement ring for a plasma processing chamber, comprising a support structure for supporting the confinement ring, wherein the support structure comprises a polymer material, wherein the polymer material is coated by a plasma resistant atomic layer deposition coating.

10. The confinement ring of claim 9, wherein the polymer material comprises polyimide.

11. The confinement ring of claim 9, wherein the plasma resistant atomic layer deposition coating is alumina.

12. A method of making an electrostatic chuck for a plasma processing chamber, comprising:
providing a base comprising aluminum or aluminum alloy;
providing a ceramic top plate for holding a wafer;
bonding the ceramic top plate to the base;
applying a polymer material between the base and the ceramic top plate, having at least one exposed portion; and
depositing by atomic layer deposition a plasma resistant layer on the at least one exposed portion.

13. The method of claim 12, wherein the step of bonding comprises joining the ceramic top plate to the base with an adhesive, and the step of applying a polymer material comprises applying a polymer bead surrounding the adhesive.

14. The method of claim 12, wherein the plasma resistant atomic layer deposition coating is a dielectric material.

15. The method of claim 12, wherein the plasma resistant atomic layer deposition coating comprises alumina.

16. The method of claim 12, wherein the plasma resistant atomic layer deposition coating comprises an oxide comprising yttrium.

17. The method of claim 12, wherein the polymer material comprises strengthening additives for enhanced mechanical properties.

18. The method of claim 12, wherein the base comprises gas distribution channels.
